(19) United States
(12) Patent Application Publication
(10) Pub. No.: US 2024/0213242 A1
(43) Pub. Date: Jun. 27, 2024

(54) INTEGRATED CIRCUIT AND LOW DROP-OUT LINEAR REGULATOR CIRCUIT

(71) Applicant: Realtek Semiconductor Corporation, Hsinchu (TW)

(72) Inventor: Tzu-Chieh WEI, Hsinchu (TW)

(21) Appl. No.: 18/329,589

(22) Filed: Jun. 6, 2023

(30) Foreign Application Priority Data
Dec. 26, 2022 (TW) 111150011

(51) Int. Cl. H01L 27/088; H01L 23/482; H01L 23/485; H01L 27/02; H01L 29/423

(52) U.S. Cl. CPC H01L 27/0886; H01L 23/4824; H01L 23/485; H01L 27/0207; H01L 29/4238

(57) ABSTRACT

An integrated circuit is provided and includes multiple first conductive segments, multiple second conductive segments, multiple third conductive segments, multiple fourth conductive segments, a first conductive line, and a second conductive line. The plurality of first conductive segments and the third conductive segments are arranged between multiple first gates, and the second conductive segments and the fourth conductive segments are arranged between multiple second gates. The first conductive line transmits a drain/source signal and is coupled to the first conductive segments and the second conductive segments. The second conductive line transmits a source/drain signal and is coupled to the third conductive segments and the fourth conductive segments. The plurality of third conductive segments and the fourth conductive segments are mirrored symmetrically with respect to the second conductive line in a plan view.

### RELATED APPLICATIONS

This application claims priority to Taiwanese Application Serial Number 111150011, filed Dec. 26, 2022, which is herein incorporated by reference.

### BACKGROUND

### Technical Field

The present application relates to an integrated circuit and a low drop-out linear regulator circuit. More particularly, the present application relates to the integrated circuit and the low drop-out linear regulator circuit that have symmetrical structures.

### Description of Related Art

In some output-level circuits, multiple transistors coupled in parallel are usually applied in a limited area, thus compressing the distance between the conductive lines and causing an increase in parasitic capacitance. The parasitic capacitance causes high frequency voltage noise at the output when transmitting high frequency signals. In addition, in order to maintain a high level of circuit reliability, semiconductor layouts with a large area of conductive lines and metal routing are often used, which increases manufacturing costs.

### SUMMARY

Some aspects of the present application are to provide an integrated circuit including multiple first conductive segments and multiple second conductive segments that are separated from each other in a first direction; multiple third conductive segments and multiple fourth conductive segments that are separated from each other along the first direction, wherein the first conductive segments and the third conductive segments are arranged between multiple first gates, and the second conductive segments and the fourth conductive segments are arranged between multiple second gates; a first conductive line configured to transmit a drain/source signal and coupled to the first conductive segments and the second conductive segments; and a second conductive line configured to transmit a source/drain signal and coupled to the third conductive segments and the fourth conductive segments, wherein the third conductive segments and the fourth conductive segments are mirrored symmetrically with respect to the second conductive line in a plan view.

Some aspects of the present application are to provide an integrated circuit including multiple active areas, separated from each other in a first direction; a first conductive line having a comb structure and comprising multiple first branch portions, wherein a first branch of the first branch portions is coupled to two of the active areas adjacent to each other by multiple first conductive segments and multiple second conductive segments, wherein the first conductive segments and the second conductive segments are arranged between the two of the active areas; and a second conductive line having a comb configuration and comprising multiple second branch portions, wherein the second branch portions are interleaved with the active areas.

Some aspects of the present application are to provide a low drop-out linear regulator circuit including a first conductive line and a second conductive line; and an output stage circuit comprising multiple first conductive segments and multiple second conductive segments, wherein the first conductive segments and the second conductive segments are mirrored with respect to a first direction and correspond to a source/drain of the output stage circuit; and multiple first active regions arranged in a first active area and multiple second active regions arranged in a second active area, wherein the first active area and the second active area are arranged between the first conductive line and the second conductive line, and the first active regions and the second active regions are coupled to the second conductive line by the first conductive segments and the second conductive segments, separately.

### BRIEF DESCRIPTION OF THE DRAWINGS

The disclosure can be more fully understood by reading the following detailed description of the embodiment, with reference made to the accompanying drawings as follows:

FIG. 1 illustrates a schematic diagram of a low drop-out linear regulator circuit, in accordance with some embodiments.

FIG. 2 illustrates a schematic diagram of a low drop-out linear regulator circuit, in accordance with some embodiments.

FIG. 3 illustrates a schematic view in plan view corresponding to an integrated circuit in FIG. 1 or FIG. 2, in accordance with some embodiments.

FIG. 4 shows a schematic view of the integrated circuit 40 in plan view corresponding to FIG. 1 or FIG. 2, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, the term “and/or” includes any and all combinations of one or more of the associated listed items.

In the present application, “connected” or “coupled” may refer to “electrically connected” or “electrically coupled.” “Connected” or “coupled” may also refer to operations or actions between two or more elements.

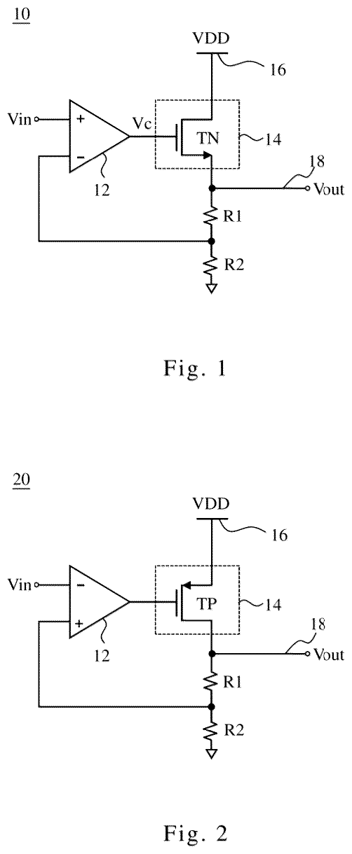

Reference is now made to FIG. 1. FIG. 1 illustrates a schematic diagram of a low drop-out linear regulator circuit 10, in accordance with some embodiments. As shown in FIG. 1, the low drop-out linear regulator circuit 10 includes an operational amplifier 12, an output stage circuit 14 and resistor units R1 to R2. The output stage circuit 14 and the resistor units R1 to R2 are coupled between the supply voltage terminal 16 and a ground terminal. The supply voltage terminal 16 is configured to provide the supply voltage VDD. The output terminal 18 is coupled between the output stage circuit 14 and the resistor unit R1.

A positive input terminal of the operational amplifier 12 receives an input signal Vin, while a negative input of the operational amplifier 12 receives a divided voltage for an output signal Vout through the resistive cells R1 to R2. In some embodiments, the operational amplifier 12 outputs a signal Vc to the output stage circuit 14 to adjust the output signal Vout according to the input signal Vin and the divided voltage of the output signal Vout.

As illustratively shown in FIG. 1, the output stage circuit 14 includes an N-type transistor TN. In some embodiments, the N-type transistor TN is a Metal-Oxide-Semiconductor Field-Effect Transistor (MOSFET) with N-type doping. Accordingly, the operational amplifier 12 outputs the signal Vc to the control terminal (gate) of the N-type transistor TN.

Reference is now made to FIG. 2. FIG. 2 illustrates a schematic diagram of a low drop-out linear regulator circuit (also referred to as low-voltage differential linear regulator circuit) 20, in accordance with some embodiments. With respect to the embodiments in FIG. 2, the same component symbols are configured to denote the same components as in FIG. 1 for ease of understanding. For the sake of simplicity, the specific operations of similar components that have been discussed in detail in the above paragraphs are omitted from this document, unless it is necessary to introduce the collaboration with the components shown in FIG. 2.

Compared with the low drop-out linear regulator circuit 10 of FIG. 1, the output stage circuit 14 in the low drop-out linear regulator circuit 20 includes a P-type transistor TP. In some embodiments, the P-type transistor TP is a metal oxide semiconductor field-effect transistor having a P-type doping. In addition, the negative input terminal of the operational amplifier 12 in FIG. 2 is configured to receive the input signal Vin and the positive input terminal receives the divided voltage corresponding to the output signal Vout. Thus, the operational amplifier 12 outputs the signal Vc to the control terminal (gate) of the P-type transistor TP.

The configurations of FIGS. 1 to 2 are given for illustrative purposes. The various embodiments of FIGS. 1 to 2 are within the contemplated scope of an embodiment of the present case. For example, in some embodiments, the output stage circuit 14 may include multiple transistors connected in parallel with each other between the supply voltage terminal 16 and the output terminal 18.

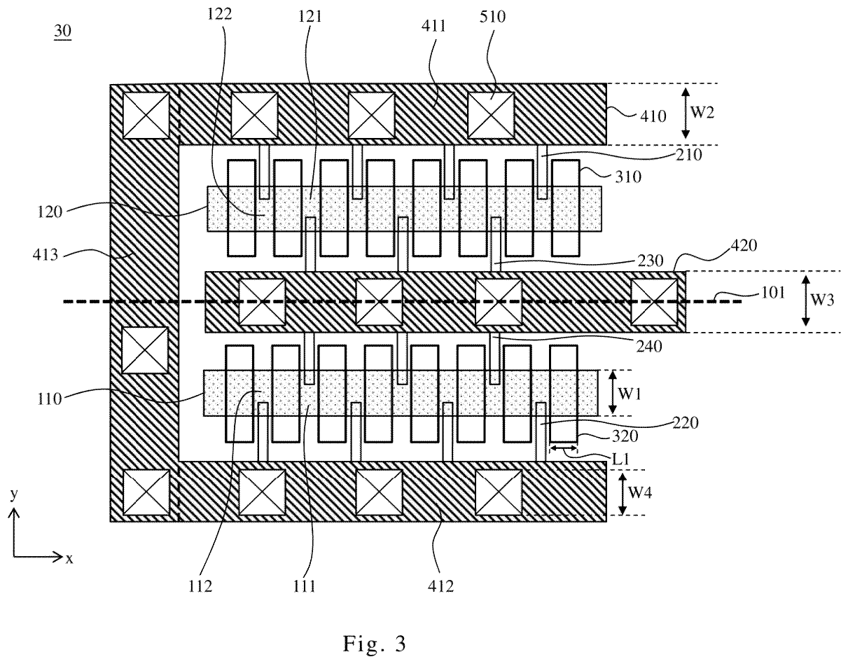

Reference is made to FIG. 3. FIG. 3 illustrates a schematic view in plan view corresponding to an integrated circuit 30 in FIG. 1 or FIG. 2, in accordance with some embodiments.

As shown in FIG. 3, the integrated circuit 30 includes active areas 110 to 120, conductive segments 210, conductive segments 220, conductive segments 230, conductive segments 240, gates 310, gates 320, a conductive line 410, a conductive line 420, and through holes 510.

In some embodiments, the conductive segments 210 and the conductive segments 220 correspond to the drain/source terminal of the N-type transistor TN in the FIG. 1 or the drain/source terminal of the P-type transistor TP in the FIG. 2. The conductive segments 230 and the conductive segments 240 correspond to the source/drain terminal of the N-type transistor TN in the FIG. 1 or the source/drain terminal of the P-type transistor TP in the FIG. 2. The gates 310 and 320 correspond to the gates of the N-type transistor TN in FIG. 1 or the gates of the P-type transistor TP in FIG. 2. For the sake of brevity, the embodiments of the present disclosure are described below with respect to the integrated circuit 30 corresponding to the N-type transistor TN in FIG. 1.

In the embodiment illustrated in FIG. 3, the structures in the integrated circuit 30 are of mirror symmetry with respect to the line segment 101 extending in the x direction. In some embodiments, the conductive line 420 extends in the x direction and is arranged in the middle of the active areas 110 to 120; in other words, the structures in the integrated circuit 30 mirror symmetrically with respect to the conductive line 420 in a planar perspective.

Specifically, the active areas 110 to 120 extend in the first semiconductor layer in the x direction and are separated from each other in the y direction. The active areas 110 to 120 are arranged between the conductive line 410 and the conductive line 420. As shown in the embodiment of FIG. 3, the active areas 110 to 120 are on opposite sides of the conductive line 420 respectively and are surrounded by the conductive line 410.

The conductive segments 210 to the conductive segments 240 are arranged in a second semiconductor layer above the first semiconductor layer along the x direction in a separate arrangement . The conductive segments 210 and the conductive segments 230 are arranged between gates 310 extending along y direction, and the conductive segments 220 and the conductive segments 240 are arranged between gates 320 extending along y direction. In some embodiments, the gates 310 and the gates 320 are arranged in the second semiconductor layer.

The conductive segments 210 and the conductive segments 220 are separated from each other along the y direction and are mirrored with respect to the x direction or the conductive line 420. The conductive segments 210 extend in the y direction from a branch portion 411 of the conductive line 410 towards the active area 120 and are configured to couple multiple active regions 122 of the active area 120 to the conductive line 410, in which the active regions 122 are between the gates 310. On the other hand, the conductive segments 220 extend in the y direction from the branch portion 412 of the conductive line 410 towards the active area 110 and are configured to couple the active regions 112 of the active area to the conductive line 410, in which the active regions 122 are between the gates 320. In some embodiments, the branch portion 413 of the conductive line 410 extends in the y direction and is coupled between the branch portion 411 and the branch portion 412.

Similarly, the conductive segments 230 and the conductive segments 240 are separated from each other along the y direction and are mirrored in the x direction or the conductive line 420. The conductive segments 230 extend from the conductive line 420 in the y direction towards the active area 120 and are configured to couple multiple active regions 121 of the active area 120 to the conductive line 420, in which the active regions 121 are between the gates 310. On the other hand, the conductive segments 240 extend from the conductive line 420 in the y direction towards the active area 110 and are configured to couple multiple active regions 111 of the active area 110 to the conductive line 420, in which the active regions 111 are between the gates 320.

As shown in FIG. 3, along the y direction, the active areas 110 to 120 have width W1, the branch portion 411 and the branch portion 412 of conductive line 410 have width W2, the conductive line 420 has width W3, and the through holes 510 has width W4. In some embodiments, since the design rule checking (DRC) in the manufacturing process of the integrated circuit indicates that the spacing between the gates 310 and the gates 320 has to be at least greater than a specific threshold. Accordingly, the width W3 of the conductive line 420 is greater than the width W2 of the branch portions 411 and 412 that are located on sides of the conductive line 420 (e.g., referred to as the outside of the integrated circuit 30.) In some embodiments, the width W1 of the active areas 110 to 120 is between the widths W2 and W3. In some embodiments, the width W3 may be approximately 1.4 times the width W2, and the width W3 may be approximately 1.1 times the width W1. In addition, the gates 310 and the gates 320 have a length L1 along the x direction. In some embodiments, the length L1 is between the width W1 and the width W2.

In some embodiments, the conductive line 410 is configured to transmit a drain/source signal and the conductive line 420 is configured to transmit a source/drain signal. For example, with reference to both FIGS. 1 and 3, the conductive line 410 transmits the drain/source signal between the drain/source terminal of the N-type transistor TN and the supply voltage terminal 16, i.e., the conductive line 410 is configured as an input terminal of the output stage circuit 14 to receive the supply voltage VDD. The conductive line 420 transmits the source/drain signal between the source/drain terminal of the N-type transistor TN and the output terminal 18, i.e., the conductive line 420 is configured as the output terminal 18 of the output stage circuit 14.

In some embodiments, the conductive line 410 and the conductive line 420 are arranged in a third semiconductor layer above the second semiconductor layer and receive or transmit signals to other conductive connections in a fourth semiconductor layer above the third semiconductor layer through the through holes 510. For example, the conductive line 410 and the conductive line 420 may be metal-zero (M0) layers and the other conductive connections mentioned above may be metal-one (M1) layers or higher metal conductive connections. In some embodiments, the conductive line 410 and the conductive line 420 are thinner than the other conductive connections in the z-direction, so that the conductive line 410 and the conductive line 420 may be considered as thin metal layers and the other conductive connections may be considered as thick metal layers. In some embodiments, the width W2 of the branch portion 411 and the branch portion 412 of the conductive line 410 and the width W3 of the conductive line 420 need to be greater than the width W4 of the through holes 510 in order for the conductive line 410 and the conductive line 420 to be securely connected to the thick metal layer through the through holes 510.

The configurations of FIGS. 1 to 3 are given for illustrative purposes. The various embodiments of FIGS. 1 to 3 are within the contemplated scope of an embodiment of the present case. For example, in some embodiments, the conductive line 410 is configured to transmit a source/drain signal and the conductive line 420 is configured to transmit a drain/source signal.

In general low drop-out linear regulator circuits, multiple transistors coupled in parallel are usually applied as output stage circuits within a limited area, thus compressing the distance between the conductive lines connecting the drain and source terminals of the transistors. It results in an increase in parasitic capacitance. The parasitic capacitance forms a feedforward path to the output, causing high frequency voltage noises at the output when transmitting high frequency signals. In addition, in order to maintain the high reliability of the circuit against high voltages and large currents, a semiconductor layout with a large area of conductive lines and metal winding is necessary, which increases the manufacturing cost.

The layout of the IC provided by this application contains only a single conductive line in the adjacent active area. In other words, the distance between the two conductive lines increases, thus reducing the parasitic capacitance between the conductive lines and reducing the output of high frequency voltage noises through the parasitic capacitance. It improves product performance. At the same time, the symmetrical design proposed in the present application allows for the direct coupling of conductive segments of the same poles of the corresponding transistors with the same conductive line, significantly cutting the area required for the circuit compared to some approaches. For example, in some embodiments, the area of the integrated circuit of the present application is approximately 20% less than in some embodiments, further saving manufacturing costs.

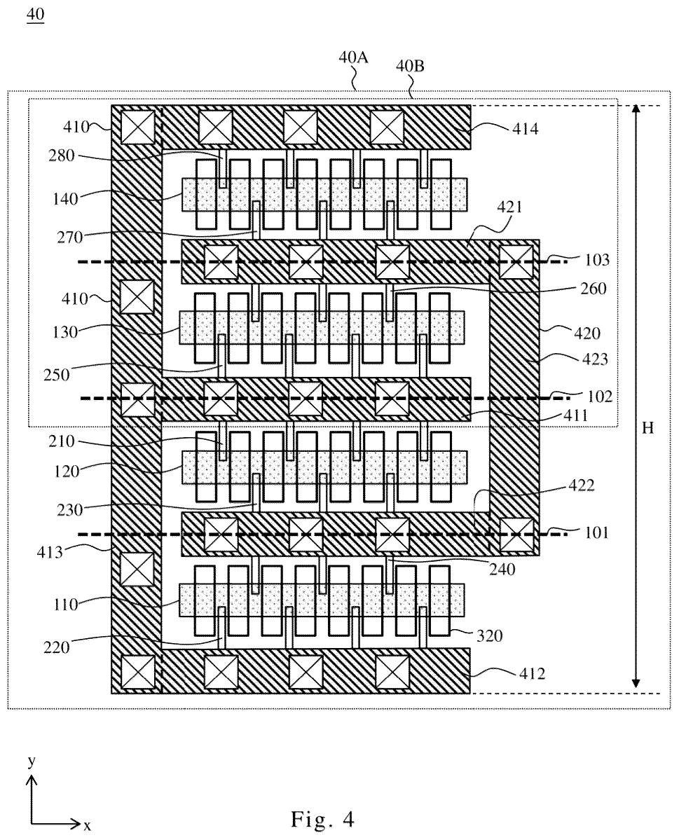

Reference is made to FIG. 4. FIG. 4 shows a schematic view of the integrated circuit 40 in plan view corresponding to FIG. 1 or FIG. 2, in accordance with some embodiments. With respect to the example in FIG. 4, the same component symbols are configured to indicate the same components as in FIGS. 1 to 3 for ease of understanding.

In some embodiments, the integrated circuit 40 further includes active areas 130 to 140 and conductive segments 250, 260, 270, and 280. The active areas are configured with respect to, for example, the active areas 110 to 120. The conductive segments 250 to 280 are configured with respect to, for example, the conductive segments 210 to 240. In some embodiments, the conductive segments 250 and the conductive segments 280 correspond to the drain/source terminal of the N-type transistor TN in FIG. 1, and the conductive segments 260 and the conductive segments 270 correspond to the source/drain terminal of the N-type transistor TN in FIG. 1.

In addition, compared with the integrated circuit 30 in FIG. 3, the conductive lines 410 and conductive lines 420 in the integrated circuit 40 have a comb structure including multiple branch portions. Specifically, the conductive line 410 includes a branch portion 414 which is parallel to the branch portion 411 and the branch portion 412 and separate from each other in the y direction, and the branch portion 413 is coupled between the branch portions 411 to 412 and the branch portion 414. The conductive line 420 includes branch portions 421-422 extending in the x direction and a branch portion 423 that extends in the y direction and is coupled between the branch portion 421 and the branch portion 422. The branch portion 421 and the branch portion 422 are staggered with the active areas 110 to 140; furthermore, the branch portion 421 is arranged between the branch portion 411 and the branch portion 414, while the branch portion 422 is arranged between the branch portion 411 and the branch portion 414.

In some embodiments, along the x direction, the number (e.g., 3 in FIG. 4) of branch portions of the conductive line 410 is different than the number (e.g., 2 in FIG. 4) of branch portions of the conductive line 420.

In the embodiment illustrated in FIG. 4, the area 40A defined by the branch portions 411 to 414 is mirrored symmetrically along the x direction. Specifically, the area 40A is mirrored symmetrically along a line segment 102. In some embodiments, the area 40B as defined by the branch portion 411 and the branch portion 414 is mirrored symmetrically along the x direction and along a line segment 103.

For example, the conductive segments 250 are mirrored symmetrically to the conductive segment 210 with respect to the line segment 102 (and branch portion 411) and are configured to couple the active area 130 to the branch portion 411. In other words, the branch portion 411 is coupled to the active areas 120 to 130 adjacent to each other by the conductive segments 210 and the conductive segments 250 that are configured mirrored symmetrically. In some embodiments, the conductive segments 250 are mirrored symmetrically to the conductive segments 210 with respect to the branch portion 411.

The conductive segments 260 to 270 are arranged between adjacent active areas 130 to 140 and are mirrored symmetrically with respect to the line segment 103 (and the branch portion 421). In some embodiments, the conductive segments 260 and the conductive segments 230 are mirrored symmetrically with respect to the branch portion 411, in which the conductive segments 230 are coupled to the branch portion 422.

In summary, the integrated circuit and the low differential linear regulator circuit of the present application provide a symmetrically arranged integrated circuit layout design. By reducing the number of conductive lines and increasing the distance between the two conductive lines, the parasitic capacitance between the conductive lines is reduced and the output of high frequency voltage noises induced by the parasitic capacitance is reduced, thereby improving product performance and saving manufacturing costs.

Although the present application has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present application without departing from the scope or spirit of the disclosure. In view of the foregoing, it is intended that the present application cover modifications and variations of this disclosure provided they fall within the scope of the following claims.

What is claimed is:

1. An integrated circuit, comprising:
a plurality of first conductive segments and a plurality of second conductive segments that are separated from each other in a first direction;
a plurality of third conductive segments and a plurality of fourth conductive segments that are separated from each other along the first direction, wherein the plurality of first conductive segments and the plurality of third conductive segments are arranged between a plurality of first gates, and the plurality of second conductive segments and the plurality of fourth conductive segments are arranged between a plurality of second gates;
a first conductive line configured to transmit a drain/source signal and coupled to the plurality of first conductive segments and the plurality of second conductive segments; and
a second conductive line configured to transmit a source/drain signal and coupled to the plurality of third conductive segments and the plurality of fourth conductive segments, wherein the plurality of third conductive segments and the plurality of fourth conductive segments are mirrored symmetrically with respect to the second conductive line in a plan view.

2. The integrated circuit of claim 1, wherein the plurality of first conductive segments and the plurality of second conductive segments are mirrored symmetrically with respect to the second conductive line.

3. The integrated circuit of claim 1, further comprising:
a first active area coupled to the plurality of first conductive segments and the plurality of third conductive segments, and having a first width along the first direction,
wherein the plurality of first conductive segments to the plurality of fourth conductive segments extend in the first direction, and the second conductive line extends in a second direction different from the first direction and has a second width along the first direction, in which the second width is greater than the first width.

4. The integrated circuit of claim 3, wherein the first conductive line has a third width different from the second width along the first direction.

5. The integrated circuit of claim 4, wherein the third width is less than the first width and the second width.

6. The integrated circuit of claim 3, further comprising:
a second active area coupled to the plurality of second conductive segments and the plurality of fourth conductive segments,
wherein the second conductive line is arranged between the first active area and the second active area.

7. The integrated circuit of claim 1, further comprising:
a plurality of fifth conductive segments coupled to a first portion of the first conductive line, wherein the plurality of fifth conductive segments and the plurality of first conductive segments are mirrored symmetrically with respect to the first portion of the first conductive line,
wherein a second portion of the first conductive line is coupled to the plurality of second conductive segments, and the first portion and the second portion extend in a second direction different from the first direction.

8. The integrated circuit of claim 7, further comprising:
a plurality of sixth conductive segments coupled to the second conductive line, wherein the plurality of sixth conductive segments and the plurality of third conductive segments are mirrored symmetrically with respect to the first portion of the first conductive line.

9. The integrated circuit of claim 1, further comprising:
a plurality of fifth conductive segments coupled to a first portion of the second conductive line, wherein the plurality of third conductive segments are coupled to a second portion of the second conductive line,
wherein the first portion and the second portion extend in a second direction different from the first direction, and a third portion of the second conductive line is coupled between the first portion and the second portion.

10. The integrated circuit of claim 9, further comprising:
a plurality of sixth conductive segments, a plurality of seventh conductive segments and a plurality of eighth conductive segments, wherein the plurality of sixth conductive segments and the plurality of eighth conductive segments are mirrored symmetrically with respect to the first portion of the second conductive line, and
the plurality of fifth conductive segments and the plurality of seventh conductive segments are mirror-symmetrical with respect to the first portion of the second conductive line.

11. An integrated circuit, comprising:
a plurality of active areas, separated from each other in a first direction;
a first conductive line having a comb structure and comprising a plurality of first branch portions, wherein a first branch of the plurality of first branch portions is coupled to two of the plurality of active areas adjacent to each other by a plurality of first conductive segments and a plurality of second conductive segments, wherein the plurality of first conductive segments and the plurality of second conductive segments are arranged between the two of the active areas; and
a second conductive line having a comb configuration and comprising a plurality of second branch portions, wherein the plurality of second branch portions are interleaved with the plurality of active areas.

12. The integrated circuit of claim 11, wherein an area defined by the plurality of first branch portions is mirrored symmetrically along a second direction different from the first direction.

13. The integrated circuit of claim 11, wherein a first branch of the plurality of second branch portions is arranged between the first branch of the plurality of first branch portions and a second branch of the plurality of first branch portions,
wherein that first branch of the plurality of second branch portions is coupled to other two of the plurality of active areas adjacent to each other through a plurality of third conductive segments and a plurality of fourth conductive segments, wherein the plurality of third conductive segments and the plurality of fourth conductive segments are arranged between the other two of the active areas.

14. The integrated circuit of claim 13, wherein an area defined by the first branch of the plurality of first branch portions and the second branch of the plurality of first branch portions is mirrored symmetrically along a second direction different from the first direction.

15. The integrated circuit of claim 11, wherein the first conductive line is configured as an input terminal of an output stage circuit to receive a supply voltage, and the second conductive line is configured as an output terminal of the output stage circuit.

16. The integrated circuit of claim 11, wherein a number of the plurality of first branch portions is different from a number of the plurality of second branch portions.

17. A low drop-out linear regulator circuit, comprising:
a first conductive line and a second conductive line; and
an output stage circuit, comprising:
a plurality of first conductive segments and a plurality of second conductive segments, wherein the plurality of first conductive segments and the plurality of second conductive segments are mirrored with respect to a first direction and correspond to a source/drain of the output stage circuit; and
a plurality of first active regions arranged in a first active area and a plurality of second active regions arranged in a second active area, wherein the first active area and the second active area are arranged between the first conductive line and the second conductive line, and
the plurality of first active regions and the plurality of second active regions are coupled to the second conductive line by the plurality of first conductive segments and the plurality of second conductive segments, separately.

18. The low drop-out linear regulator circuit of claim 17, wherein the output stage circuit further comprises:
a plurality of third conductive segments and a plurality of fourth conductive segments that are mirrored with respect to the first direction and corresponding to a drain/source terminal of the output stage circuit; and
a plurality of third active regions arranged in the first active area and a plurality of fourth active regions arranged in the second active area, wherein the plurality of third active regions and the plurality of fourth active regions are coupled to the second conductive line through the plurality of fourth conductive segments and the plurality of third conductive segments, separately.

19. The low drop-out linear regulator circuit of claim 18, wherein the output stage circuit further comprises:
a plurality of fifth conductive segments coupled to the first conductive line and corresponding to the drain/source terminal of the output stage circuit, wherein the plurality of fifth conductive segments and the plurality of third conductive segments are mirrored with respect to the first direction.

20. The low drop-out linear regulator circuit of claim 17, wherein the first conductive line further comprises a first portion and a second portion extending in the first direction,
wherein the output stage circuit further comprises a plurality of third conductive segments corresponding to a drain/source terminal of the output stage circuit and a plurality of fourth conductive segments,
wherein the plurality of third conductive segments extend from the first portion towards the second active area in a second direction different from the first direction, and
the plurality of fourth conductive segments extend in the second direction from the second portion towards the first active area.
